(19) United States
(12) Patent Application Publication
(10) Pub. No.: US 2017/0069560 A1
(43) Pub. Date: Mar. 9, 2017

(54) AIR CAVITY PACKAGE

(71) Applicant: MATERION CORPORATION, Mayfield Heights, OH (US)

(72) Inventors: Richard J. Koba, Saugus, MA (US); Chee Kong Lee, Euro Asia Park (SG); Wei Chuan Goh, Skudai (MY); Joelle Ng, Parc Bleu (SG)

(21) Appl. No.: 14/652,326

(22) PCT Filed: May 22, 2015
(86) PCT No.: PCT/US15/32124

§ 371 Date: Jun. 15, 2015

Related U.S. Application Data
(60) Provisional application No. 62/002,336, filed on May 23, 2014.

(51) Int. Cl. H01L 23/373; H01L 23/047; H01L 21/48; H01L 23/10

(52) U.S. Cl. CPC H01L 23/373; H01L 23/10; H01L 23/047; H01L 21/4807; H01L 21/4871; H01L 23/3732; H01L 23/3736; H01L 23/3738; H01L 23/3731; H01L 23/3735

(57) ABSTRACT

An air cavity package includes a dielectric frame that is formed from a polyimide or a liquid crystal polymer (LCP). The dielectric frame is joined to a flange and to electrical leads using a polyimide adhesive.

### CROSS-REFERENCE TO RELATED APPLICATIONS

This application is a 371 of PCT Application No. PCT/US2015/032124, filed May 22, 2015, which claims priority to U.S. Provisional Application Ser. No. 62/002,336, filed May 23, 2014, which is hereby incorporated by reference in its entirety.

### BACKGROUND

The present disclosure relates to air cavity packages and methods for making the same.

An air cavity package typically includes one or more semiconductor dice attached to a base/flange and surrounded by a frame with electrical leads embedded in the frame. The dice are electrically joined to the leads, and the package is then sealed with a lid. The air serves as an electrical insulator due to its low dielectric constant. Air cavity packages are extensively used for housing high frequency devices (e.g., radio-frequency dice). Surrounding a high frequency semiconductor chip with air improves the high frequency properties of the die and corresponding electrical leads compared to encapsulation in a material having a higher dielectric constant (e.g., a molding compound such as epoxy).

RF device manufacturers desire to minimize material and production costs associated with air cavity packages. Manufacturers have developed metallization systems that enable silicon (Si) and gallium nitride/silicon carbide (GaN/SiC) chips to be soldered onto copper flanges using a thin gold-tin (AuSn) solder. However, it is difficult to bond a dielectric frame to the copper flange and to the electrical leads which satisfies desired cycle properties (e.g., adherence after 1,000 temperature cycles of minus 50° C. to +80° C.). The dielectric frame is typically made of alumina, but bonding alumina to copper is problematic due to the severe mismatch between the coefficients of thermal expansion (CTEs) of these materials. In particular, the linear CTE of copper 20° C. An alumina frame glued to a copper flange can only withstand thermal excursions that remain below about 190° C.

Some manufacturers have offered a dielectric frame made of liquid crystal polymer (LCP) which is overmolded onto copper leads to create a frame. LCP has a close CTE match to copper. The frame/lead subassembly can then be bonded onto a copper flange (after chips have been AuSn soldered onto the flange) using epoxy. However, LCP is difficult to bond with epoxy due to its extreme chemical inertness. A common failure mechanism of LCP parts is leakage at the interface between the LCP and a metal (e.g., as observed during gross leak testing in a Fluorinert® bath). Sometimes the flange must be sandblasted in order to achieve adequate adhesion between the flange and the LCP frame. Additionally, steps such as bonding the LCP frame to the flange between die attachment and wire bonding are necessary.

It would be desirable to develop new air cavity packages that are simpler and/or less expensive to produce. It would also be desirable to create an air cavity package with a copper base/flange that is fully assembled with a plastic frame and electrical leads, and that can withstand subsequent assembly operations (e.g., AuSn die attachment and lid attachment) that reach temperatures of 230° C. and can withstand temperature cycling (from minus 50° C. to +85° C. for one thousand cycles).

### BRIEF DESCRIPTION

The present disclosure relates to air cavity packages including a dielectric frame made of a polyimide or a liquid crystal polymer (LCP). Such air cavity packages can be highly stable during temperature cycling, since all materials share approximately the same coefficient of thermal expansion.

Disclosed in various embodiments herein is an air cavity package adapted to contain a die, comprising: a flange having an upper surface; and a dielectric frame having an upper surface and a lower surface, the lower surface being attached to the upper surface of the flange; wherein the dielectric frame is made of a polyimide or a liquid crystal polymer.

The air cavity package may further comprise a first conductive lead and a second conductive lead, attached to opposite sides of the upper surface of the dielectric frame. The first conductive lead and the second conductive lead can be attached to the upper surface of the dielectric frame by a thermoplastic polyimide. The first conductive lead and the second conductive lead can be made of copper, nickel, a copper alloy, a nickel-cobalt ferrous alloy, or an iron-nickel alloy. The copper alloy may be selected from the group consisting of CuW, CuMo, CuMoCu, and CPC.

The flange can be made of copper, a copper alloy, aluminum, an aluminum alloy, AlSiC, AlSi, Al/diamond, Al/graphite, Cu/diamond, Cu/graphite, Ag/diamond, CuW, CuMo, Cu:Mo:Cu, Cu:CuMo:Cu (CPC), Mo, W, metallized BeO, or metallized AlN.

In some embodiments, the flange is a substrate plated with one or more metal sublayers. The one or more metal sublayers can be made of nickel (Ni), gold (Au), palladium (Pd), chromium (Cr), or silver (Ag).

The dielectric frame may be attached to the surface via a thermoplastic polyimide.

In some embodiments, the dielectric frame further comprises a filler. The filler can be selected from the group consisting of ceramic powder, glass powder, and chopped glass fibers.

The dielectric frame may have a dielectric constant of about 3.0 to about 5.0.

Also disclosed are methods for forming an air cavity package, comprising: joining a lower surface of a dielectric frame to an upper surface of a flange using a first adhesive composition; joining a first conductive lead and a second lead to an upper surface of the dielectric frame using a second adhesive composition; and curing the first adhesive composition and the second adhesive composition, either separately or simultaneously; wherein the dielectric frame comprises a polyimide or a liquid crystal polymer.

The first adhesive composition and the second adhesive composition may be a thermoplastic polyimide. Sometimes, the first adhesive composition and the second adhesive composition are cured simultaneously.

The curing can be performed at a temperature of about 220° C. and a pressure of about 10 psi. The flange may be formed of a copper substrate plated with gold.

Sometimes, the methods can further comprise attaching a die to the upper surface of the flange, wherein the dielectric frame surrounds the die.

Also disclosed are methods for forming an air cavity package, comprising: receiving a polyimide sheet laminated on a lower surface and an upper surface with a conductive material; and shaping the upper surface of the polyimide sheet to form electrical leads on opposite sides of a cavity in the polyimide sheet, the conductive material on the lower surface of the polyimide sheet being visible in the cavity. The conductive material can be copper.

These and other non-limiting characteristics of the disclosure are more particularly disclosed below.

### BRIEF DESCRIPTION OF THE DRAWINGS

The following is a brief description of the drawings, which are presented for the purposes of illustrating the exemplary embodiments disclosed herein and not for the purposes of limiting the same.

FIG. 1 is an exploded view of an exemplary air cavity package according to the present disclosure.

FIG. 2 is a side view of the air cavity package of FIG. 1.

FIG. 3 is a top view of the air cavity package of FIG. 1.

### DETAILED DESCRIPTION

A more complete understanding of the components, processes and apparatuses disclosed herein can be obtained by reference to the accompanying drawings. These figures are merely schematic representations based on convenience and the ease of demonstrating the present disclosure, and are, therefore, not intended to indicate relative size and dimensions of the devices or components thereof and/or to define or limit the scope of the exemplary embodiments.

Although specific terms are used in the following description for the sake of clarity, these terms are intended to refer only to the particular structure of the embodiments selected for illustration in the drawings, and are not intended to define or limit the scope of the disclosure. In the drawings and the following description below, it is to be understood that like numeric designations refer to components of like function.

The singular forms “a,” “an,” and “the” include plural referents unless the context clearly dictates otherwise.

As used in the specification and in the claims, the term “comprising” may include the embodiments “consisting of” and “consisting essentially of.” The terms “comprise(s),” “include(s),” “having,” “has,” “can,” “contain(s),” and variants thereof, as used herein, are intended to be open-ended transitional phrases, terms, or words that require the presence of the named components/steps and permit the presence of other components/steps. However, such description should be construed as also describing compositions or processes as “consisting of” and “consisting essentially of” the enumerated components/steps, which allows the presence of only the named components/steps, along with any impurities that might result therefrom, and excludes other components/steps.

Numerical values should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently combinable (for example, the range of “from 2 grams to 10 grams” is inclusive of the endpoints, 2 grams and 10 grams, and all the intermediate values).

The terms “substantially” and “about” can be used to include any numerical value that can vary without changing the basic function of that value. When used with a range, “substantially” and “about” also disclose the range defined by the absolute values of the two endpoints, e.g. “about 2 to about 4” also discloses the range “from 2 to 4.” The terms “substantially” and “about” may refer to plus or minus 10% of the indicated number.

Some terms used herein are relative terms. In particular, the terms “upper” and “lower” are relative to each other in location, i.e. an upper component is located at a higher elevation than a lower component in a given orientation, but these terms can change if the component is flipped. When different components are compared to each other though, these terms refer to the components being in a fixed orientation relative to each other. For example, a lower surface of a first component will always rest upon an upper surface of a second component that is located below the first component; the first component cannot be flipped by itself so that its upper surface then rests upon the upper surface of the second component.

The terms “above” and “below” are relative to an absolute reference; a first component that is above a second component is always at a higher elevation.

As used herein, the term “coefficient of thermal expansion” or “CTE” refers to the linear coefficient of thermal expansion at 20° C.

When an element is named alone, e.g. “aluminum”, this usage refers to the element with only impurities present, e.g. pure aluminum. When used in conjunction with the term “alloy”, this usage refers to an alloy containing a majority of the named element.

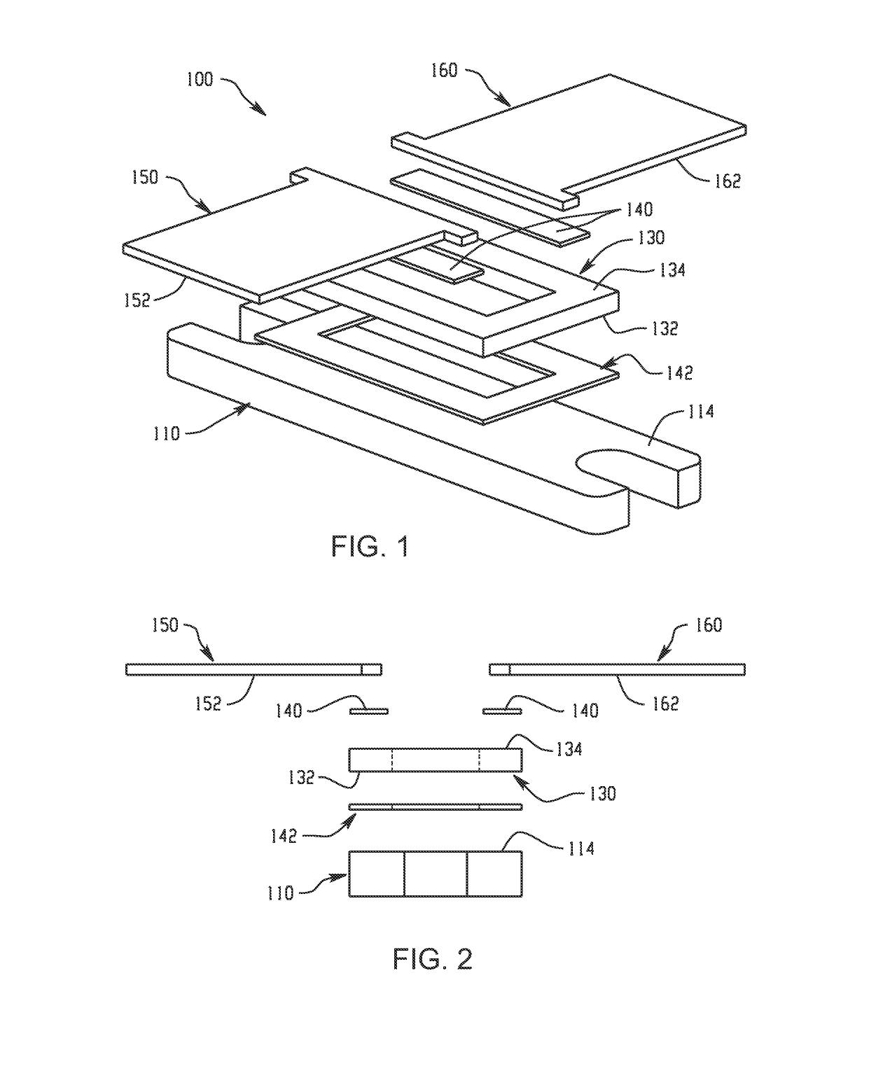

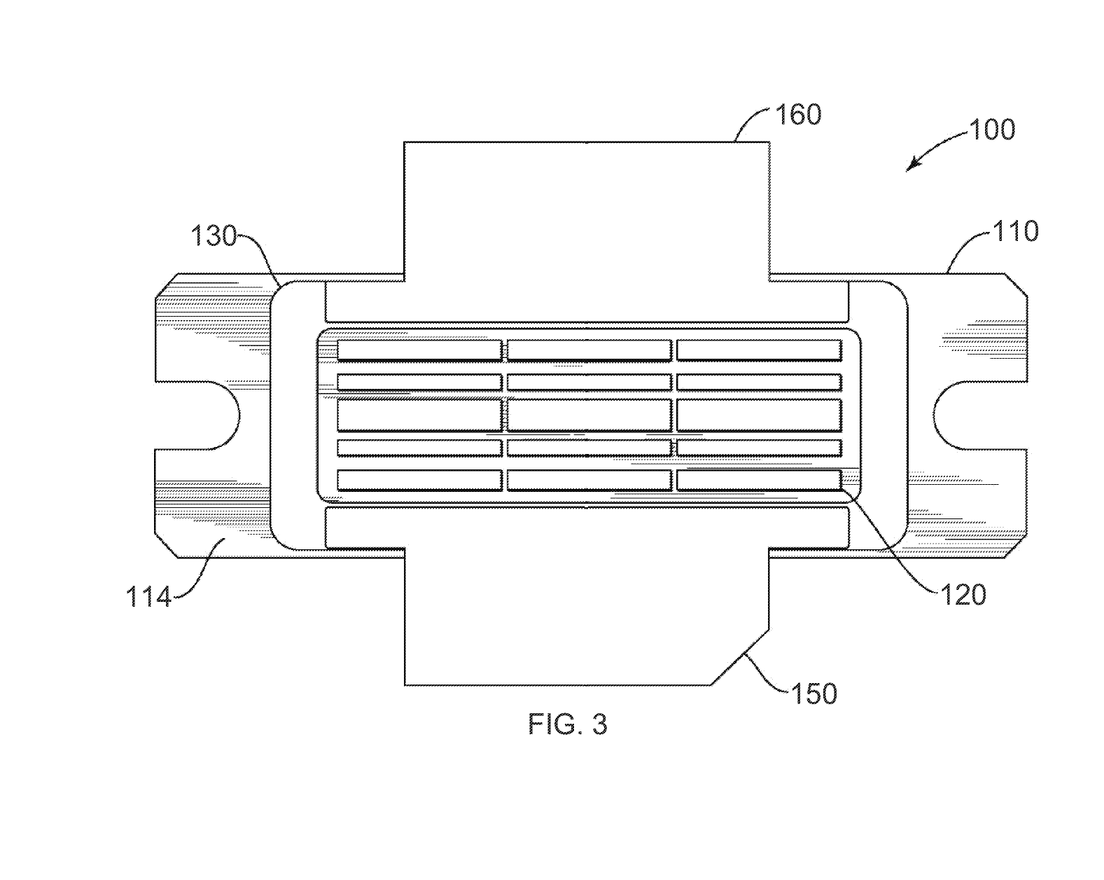

FIG. 1 illustrates an exploded view of an embodiment of an air cavity package 100 according to the present disclosure. FIG. 2 is a side view of the air cavity package. FIG. 3 is a top view of the air cavity package.

The air cavity package 100 includes a flange 110, a semiconductor die 120, a first conductive lead 150, a second conductive lead 160, and a dielectric frame 130. The flange is also referred to as the base of the air cavity package. An upper surface 134 of the dielectric frame 130 is attached to the lower surface 152, 162 of each conductive lead 150, 160 by a first adhesive composition 140. The conductive leads 150, 160 are located on opposite sides of the package 100, or opposite sides of the dielectric frame 130 or the flange 110. A lower surface 132 of the dielectric frame 130 is attached to an upper surface 114 of the flange 110 by a second adhesive composition 142. The dielectric frame 130 surrounds and encloses the die 120, which is also attached to the upper surface 114 of the flange. The dielectric frame has an annular shape, i.e. a shape defined by the area between two concentric shapes.

The flange 110 acts as a heat sink for the semiconductor die, and is made of a material with medium to high thermal conductivity. The flange can be made of copper, aluminum, AlSiC, AlSi, Al/diamond, Al/graphite, Cu/diamond, Cu/graphite, Ag/diamond, CuW, CuMo, Cu:Mo:Cu, Cu:CuMo:Cu (CPC), Mo, W, metallized BeO, or metallized AlN. It is noted that CPC refers to Cu:CuMo70:Cu, which usually has thicknesses of 1:4:1 for the three sublayers. It is noted that the flange can be a metal matrix composite, such as graphite dispersed within an aluminum or copper metal matrix. In particular embodiments, the flange is in the form of a substrate that is plated with one or more metal sublayers on each major surface (e.g., a plating material compatible with AuSn die attachment). The flange can be plated with combinations of nickel (Ni), gold (Au), palladium (Pd), chromium (Cr), and silver (Ag), as desired. In particular combinations, the flange is plated with Ni+Au, Ni+Pd+Au, Ni+Cr, Pd+Au, or Ni+Ag, with the first listed element being plated first (i.e. closest to the substrate).

The adhesive compositions 140, 142 generally include a strong, ductile high temperature adhesive (e.g., a thermoplastic polyimide, or other polyimide-based adhesive). Thermoplastic polyimide exhibits strong adhesive strength between the flange 110 and the dielectric frame 130.

The first adhesive composition 140 and the second adhesive composition 142 may be the same or different. The adhesive compositions 140, 142 may consist of the main adhesive material or may include one or more other components. In some embodiments, the adhesive composition is filled with a dielectric material (e.g., glass and/or ceramic powder). Other adhesives may be applied in a layer above and/or below the main adhesive. In some embodiments, the main adhesive is a thermoplastic polyimide and the other adhesive is a high temperature epoxy or a high temperature polyimide-based adhesive.

The thermoplastic polyimide can be in the form of an A-stage adhesive, in which the polyimide is still liquid and a relatively significant amount of solvent is still present. This A-stage thermoplastic polyimide can dispensed, dipped, pad printed, or screen printed onto a surface and subsequently B-staged. Alternatively, the adhesive is a B-staged film, in which the majority of solvent has been previously removed and the adhesive is uncured, but can be handled and shaped relatively easily. The free standing B-staged thermoplastic polyimide film can be stamped into a preform; or a B-staged thermoplastic polyimide can be coated on both faces of a thin polyimide (e.g., Kapton®) film. Thermoplastic polyimide provides a fast-acting bond and is suitable for high temperature operations. It is noted that polyimides intrinsically are thermal insulators and do not conduct heat very well. Polyimides are also intrinsically electrically isolating, i.e. they do not conduct electricity.

Non-limiting examples of polyimide adhesives include adhesives sold by Polytec PT GmbH of Waldbronn, Germany and Fraivillig Technologies of Boston, Massachusetts. Exemplary Polytec adhesives include adhesives sold under the trade names EC-P 280, EP P-690, EP P-695, and TC-P-490.

The use of thermoplastic polyimide (TPI) as an adhesive to assemble the air cavity package provides flexibility with respect to the lead and flange materials. First, this adhesive will bond well to most ceramic, metal, or glass surfaces without requiring pre-metallization of that surface. The adhesive strength is very high regardless of whether the surface being bonded is a metal, ceramic, or plastic. Cured TPI is also very compliant, i.e. has a low Young's modulus or is not very stiff. The combination of high adhesive strength with low stiffness means that cured TPI bond films can withstand severe shear stress without fracture or loss of adhesion. The cured TPI bond film can also withstand severe CTE mismatch between two surfaces being bonded together without losing adhesion to either surface. Second, this adhesive will cure at temperatures below 300° C. This reduces residual stress (CTE mismatch) between the parts being bonded together. This low temperature cure also reduces processing costs since lower-cost ovens or hot plates can be used instead of expensive high temperature furnaces.

Another advantage is that this adhesive can be operated far above its curing temperature without degrading. This permits higher operating temperatures in the final substrate, and also allows the articles to withstand higher amperage excursions compared to other adhesives. Once cured, the thermoplastic polyimide can withstand extended operation at 350° C. and thermal excursions to 450° C. By comparison, epoxy adhesives typically cure at a low temperature of around 170° C., and will debond, char, or delaminate at higher temperatures. As a result, air cavity packages made using TPI are compatible with subsequent die attach operations using conventional die bonding materials such as silver-filled epoxy, AuSn solder (280° C.), and SnAgCu solder (217° C.).

Next, the electrical leads 150, 160 may be made of copper, nickel, a copper alloy, a nickel-cobalt ferrous alloy (e.g., Kovar®), or an iron-nickel alloy (e.g., Alloy 42, i.e. Fe58Ni42). As with the flange, the electrical leads can be plated with one or more metal sublayers, which are the same as described above.

Since thermoplastic polyimide will dissolve in high pH solutions (e.g., solutions typically used in the cleaning step of electroplating processes), it is preferable for the lead and flange materials to be plated prior to assembly of the air cavity package (if they are plated).

The dielectric frame 130 is formed from a polyimide or a liquid crystal polymer (LCP). The dielectric frame 130 may have a thickness (i.e. height) of from about 0.2 mm to about 0.8 mm, including about 0.5 mm.

The dielectric frame 130 can be formed from a polyimide sheet obtained commercially under the tradenames Vespel®, Torlon®, or Cirlex®. The sheet can be machined in a variety of low cost methods such as stamping, laser cutting, water jet cutting, milling, and machining, to obtain the desired shape. A frame 130 made of polyimide may cost less than a conventional metallized and plated alumina frame.

The dielectric frame 130 may also be formed via injection molding. Polyimide resins that can be injection molded include DuPont Aurum® and Vespel® resins. Extern® UH resins (commercially available from Sabic Innovative Plastics of Pittsfield, Mass.) have an unusually high service temperature of about 240° C.

Optionally, the polyimide can be filled with an insulative, non-conducting filler to modify the properties of the dielectric frame. In some embodiments, the filler is a ceramic powder, glass powder or milled glass fibers. These fillers can reduce the CTE of the dielectric frame. The filler may be present in an amount of from greater than zero to about 50 volume percent of the dielectric frame.

An LCP can also injection molded into a net shape frame to form the dielectric frame. LCP compositions that can be injection molded include the Vectra family of LCP (Celanese Corporation) as well as Laperos (Polyplastics).

The dielectric frame may have a dielectric constant in the range of from about 3.0 to about 5.0, including from about 3.2 to about 3.8 and from about 3.4 to about 3.6.

Polyimide and LCP are suitable materials for the dielectric frame due to their dielectric properties. Table 1 lists the properties of Cirlex® and Extern® polyimides and LCP compared to conventional frame materials (i.e., alumina).

TABLE 1

| | | | | Sabic |
|---|---|---|---|---|
| | Coorstek | RJR Polymers' | Cirlex | Extem |
| | AD-96 | LCP “HTP | polyimide | UH1006 |
| Material | Alumina | 1280” | sheet | unfilled |
| Dielectric | 9.0 | 3.8 | 3.6 | 3.4 |
| Constant | | | | |
| Loss tangent | 0.0002 | 0.002 | 0.002 | 0.008 |
| Dielectric | 210 | 766 | 1200 | 550 |
| Strength | | | | |
| (V/mil) | | | | |
| Density (g/cc) | 3.72 | 1.67 | 1.42 | 1.37 |
| CTE (10-6/° C.) | 8.2 | 17 | 20 | 46 |
| Moisture | Negligible | 0.02% | 4% max | 2.1% max |
| Absorption | | | | |
| Maximum | >1000 | 250 | 340 | 250 |
| Operating | | | | |
| Temperature (° C.) | | | | |

Advantages of polyimide over LCP include higher operating temperature, compatibility with thermoplastic polyimide adhesive (which is also suitable for high temperature operation), and ability to easily bond to adhesives such as thermoplastic polyimide.

Since LCP and polyimides exhibit similar dielectric constants, components matched to LCP dielectric frames also generally work well with polyimide frames. For example, a radio frequency power transistor designed to have RF impedance match with a LCP frame will also generally have RF impedance match with a polyimide frame.

A lid (not shown) may be added to seal the air in the air cavity of the package. In some embodiments, the lid comprises alumina ceramic or LCP. An epoxy may be used to bond the lid to the top surface of the frame, including the polyimide frame and the leads (e.g., gold-plated leads). The lid epoxy may be cured at a temperature of about 160° C.

When the leads 150, 160 and flange 110 are both made of copper and the adhesive compositions 140, 142 include a thermoplastic polyimide, then the materials of these components and the dielectric frame 130 share a very similar CTE.

The leads 150, 160, dielectric frame 130, and flange 110 can be aligned in a fixture and bonded together by curing the adhesive composition. Typical curing temperature for thermoplastic polyimide is about 220° C. at 10 psi. Once cured, the thermoplastic polyimide can withstand an excursion of 320° C. for 5 minutes (e.g., to enable AuSn die attachment) followed by thermal excursions necessary for lidding and temperature cycle testing.

Alternatively, in another exemplary method, the air cavity package can be formed from a polyimide sheet that is completely laminated on both surfaces with copper. Exemplary thicknesses include 8 mil Cu/20 mil Cirlex®/8 mil Cu; and 4 mil Cu/20 mil Cirlex®/8 mil Cu. This laminated sheet can then be machined into individual air cavity packages. For example, the laminated sheet can be milled into one copper surface to create the electrical leads and the polyimide frame (i.e. by forming a cavity in the polyimide layer of the sheet such that the opposite copper surface is exposed). The opposite surface is then milled to create the flange. This method does not require the use of polyimide adhesive. Generally, the use of lamination instead of thermoplastic polyimide adhesion is better suited for the manufacture of earless headers.

Alternatively, one or both faces of copper can be photoetched to define the array of leads and bases. Thermoplastic polyimide is generally compatible with the acids used for photoetching. However, care must be exercised when stripping the photoresist in a basic solution. Photoetching has the advantage of creating air cavity packages having multiple, narrowly spaced leads.

Variations in the lamination process may be utilized to reduce post-lamination machining. For example, a sheet of polyimide (e.g., a 20 mil thick sheet of Cirlex®) can be punched with an array of thru-holes and then laminated with sheets of photoetched Cu: the top panel photoetched into an array of electrical leads and the backside panel photoetched into an array of bases or flanges. Alignment holes and pins can be used to align the Cu/polyimide/Cu stack prior to lamination. Using a high pressure excise press, the individual headers can be liberated by punching through the thickness of the sheet and tie bars.

The air cavity packages of the present disclosure may be particularly suitable for commercial devices (e.g., cellular base station amplifiers). Such devices are not typically subjected to temperature cycling in the field. Therefore, moisture uptake is reduced.

Commercial laterally diffused metal oxide semiconductor (LDMOS) silicon transistors used in base stations must be in air cavity packages compatible with Moisture Sensitivity Level 3 (MSL 3). Essentially, MSL 3 exposes the lidded assembly to 30° C.+60% relative humidity for 192 hours, followed by a specific solder reflow thermal profile that peaks at 200° C. The lidded package must then pass gross leak testing in Fluoroinert, and pass other testing requirements. Current manufacturers extensively use epoxy overmolded packages. Such packages are low cost and pass MSL 3. However, epoxy overmolded packages do not have an air cavity. Therefore, the RF properties of the transistor are degraded.

The air cavity packages of the present disclosure may generally be able to withstand the sequential steps of AuSn die attachment (320° C.), lid sealing with epoxy (160° C.), and temperature cycling (e.g., −50° C. to 85° C. for 1000 cycles).

It will be appreciated that variants of the above-disclosed and other features and functions, or alternatives thereof, may be combined into many other different systems or applications. Various presently unforeseen or unanticipated alternatives, modifications, variations or improvements therein may be subsequently made by those skilled in the art which are also intended to be encompassed by the following claims.

1. An air cavity package adapted to contain a die, comprising:
a flange having an upper surface; and
a dielectric frame having an upper surface and a lower surface, the lower surface being attached to the upper surface of the flange;
wherein the dielectric frame is made of a polyimide or a liquid crystal polymer.

2. The air cavity package of claim 1, further comprising a first conductive lead and a second conductive lead, attached to opposite sides of the upper surface of the dielectric frame.

3. The air cavity package of claim 2, wherein the first conductive lead and the second conductive lead are attached to the upper surface of the dielectric frame by a thermoplastic polyimide.

4. The air cavity package of claim 2, wherein the first conductive lead and the second conductive lead are made of copper, nickel, a copper alloy, a nickel-cobalt ferrous alloy, or an iron-nickel alloy.

5. The air cavity package of claim 4, wherein the copper alloy is selected from the group consisting of CuW, CuMo, CuMoCu, and CPC.

6. The air cavity package of claim 1, wherein the flange is made of copper, a copper alloy, aluminum, an aluminum alloy, AlSiC, AlSi, Al/diamond, Al/graphite, Cu/diamond, Cu/graphite, Ag/diamond, CuW, CuMo, Cu:Mo:Cu, Cu:CuMo:Cu (CPC), Mo, W, metallized BeO, or metallized AlN.

7. The air cavity package of claim 1, wherein the flange is a substrate plated with one or more metal sublayers.

8. The air cavity package of claim 7, wherein the one or more metal sublayers are made of nickel (Ni), gold (Au), palladium (Pd), chromium (Cr), or silver (Ag).

9. The air cavity package of claim 1, wherein the dielectric frame is attached to the surface via a thermoplastic polyimide.

10. The air cavity package of claim 1, wherein the dielectric frame further comprises a filler.

11. The air cavity package of claim 10, wherein the filler is selected from the group consisting of ceramic powder, glass powder, and chopped glass fibers.

12. The air cavity package of claim 1, wherein the dielectric frame has a dielectric constant of about 3.0 to about 5.0.

13. A method for forming an air cavity package, comprising:
joining a lower surface of a dielectric frame to an upper surface of a flange using a first adhesive composition;
joining a first conductive lead and a second lead to an upper surface of the dielectric frame using a second adhesive composition; and
curing the first adhesive composition and the second adhesive composition, either separately or simultaneously;
wherein the dielectric frame comprises a polyimide or a liquid crystal polymer.

14. The method of claim 13, wherein the first adhesive composition and the second adhesive composition are a thermoplastic polyimide.

15. The method of claim 13, wherein the first adhesive composition and the second adhesive composition are cured simultaneously.

16. The method of claim 13, wherein the curing is performed at a temperature of about 220° C. and a pressure of about 10 psi.

17. The method of claim 13, wherein the flange is formed of a copper substrate plated with gold.

18. The method of claim 13, further comprising attaching a die to the upper surface of the flange, wherein the dielectric frame surrounds the die.

19. A method for forming an air cavity package, comprising:
receiving a polyimide sheet laminated on a lower surface and an upper surface with a conductive material; and
shaping the upper surface of the polyimide sheet to form electrical leads on opposite sides of a cavity in the polyimide sheet, the conductive material on the lower surface of the polyimide sheet being visible in the cavity.

20. The method of claim 19, wherein the conductive material is copper.
